(19) United States
(12) Patent Application Publication
(10) Pub. No.: US 2021/0249307 A1
(43) Pub. Date: Aug. 12, 2021

(54) TRANSISTORS WITH ASYMMETRICALLY-POSITIONED SOURCE/DRAIN REGIONS

(71) Applicant: GLOBALFOUNDRIES U.S. Inc., Santa Clara, CA (US)

(72) Inventors: Man Gu, Malta, NY (US); Wenjun Li, Saratoga Springs, NY (US)

(21) Appl. No.: 16/783,741

(22) Filed: Feb. 6, 2020

(51) Int. Cl. H01L 21/8234; H01L 29/78; H01L 27/088; H01L 29/08

(52) U.S. Cl. CPC H01L 21/823418; H01L 29/7851; H01L 21/823431; H01L 29/0847; H01L 27/0886

(57) ABSTRACT

Structures for a field-effect transistor and methods of forming a structure for a field-effect transistor. First and second gate structures extend over a semiconductor body. The first gate structure includes a first sidewall and a second sidewall opposite the first sidewall, and the second gate structure includes a sidewall adjacent to the first sidewall of the first gate structure. A first source/drain region includes a first epitaxial semiconductor layer positioned between the first sidewall of the first gate structure and the sidewall of the second gate structure. A second source/drain region includes a second epitaxial semiconductor layer positioned adjacent to the second sidewall of the first gate structure. The first sidewall of the first gate structure and the sidewall of the second gate structure are separated by a distance that is greater than a width of the first epitaxial semiconductor layer.

### BACKGROUND

The present invention relates to semiconductor device fabrication and integrated circuits and, more specifically, to structures for a field-effect transistor and methods of forming a structure for a field-effect transistor.

Complementary-metal-oxide-semiconductor (CMOS) processes may be employed to build a combination of p-type and n-type field-effect transistors that are used as devices to construct, for example, logic cells. Field-effect transistors generally include a source, a drain, a channel region between the source and drain, and a gate electrode overlapped with the channel region. When a control voltage exceeding a characteristic threshold voltage is applied to the gate electrode, carrier flow occurs in the channel region between the source and drain to produce a device output current. A field-effect transistor may include multiple gates that overlap with multiple channel regions.

The source and drain of a field-effect transistor are simultaneously formed. One approach is to implant ions containing a p-type dopant or an n-type dopant into regions of the semiconductor body to provide the source and drain. Another approach is to epitaxially grow sections of a semiconductor material from the semiconductor body to form the source and drain. The semiconductor material may be in situ doped during epitaxial growth with either a p-type dopant or an n-type dopant.

A problem associated with wide gate pitches in a multi-gate field-effect transistor is underfilling of the semiconductor material that is epitaxially grown in cavities to form the source and drain. The underfilling may degrade device performance, such as degradation of radio-frequency performance metrics like the power gain. The underfilling may also degrade other performance metrics. As examples, the drain current when the transistor is biased in the saturation region (Idsat) may be reduced and the contact resistance may be increased.

Improved structures for a field-effect transistor and methods of forming a structure for a field-effect transistor are needed.

### SUMMARY

In an embodiment of the invention, a structure for a field-effect transistor is provided. The structure includes first and second gate structures that extend over a semiconductor body. The first gate structure includes a first sidewall and a second sidewall opposite the first sidewall, and the second gate structure includes a sidewall that is positioned adjacent to the first sidewall of the first gate structure. A first source/drain region includes a first epitaxial semiconductor layer positioned between the first sidewall of the first gate structure and the sidewall of the second gate structure. A second source/drain region includes a second epitaxial semiconductor layer positioned adjacent to the second sidewall of the first gate structure. The first epitaxial semiconductor layer has a width, and the first sidewall of the first gate structure and the sidewall of the second gate structure are separated by a distance that is greater than the width of the first epitaxial semiconductor layer.

In an embodiment of the invention, a method of forming a structure for a field-effect transistor is provided. The method includes forming a first gate structure that extends over a semiconductor body, forming a second gate structure that extends over the semiconductor body, forming a first epitaxial semiconductor layer of a first source/drain region on the semiconductor body, and forming a second epitaxial semiconductor layer of a second source/drain region on the semiconductor body. The first gate structure includes a first sidewall and a second sidewall opposite the first sidewall, and the second gate structure includes a sidewall adjacent to the first sidewall of the first gate structure. The first source/drain region is positioned between the first sidewall of the first gate structure and the sidewall of the second gate structure, and the second source/drain region is positioned adjacent to the second sidewall of the first gate structure. The first epitaxial semiconductor layer has a width, and the first sidewall of the first gate structure and the sidewall of the second gate structure are separated by a distance that is greater than the width of the first epitaxial semiconductor layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIGS. 1-10 are cross-sectional views of a structure for a fin-type field-effect transistor at successive fabrication stages of a processing method in accordance with embodiments of the invention.

### DETAILED DESCRIPTION

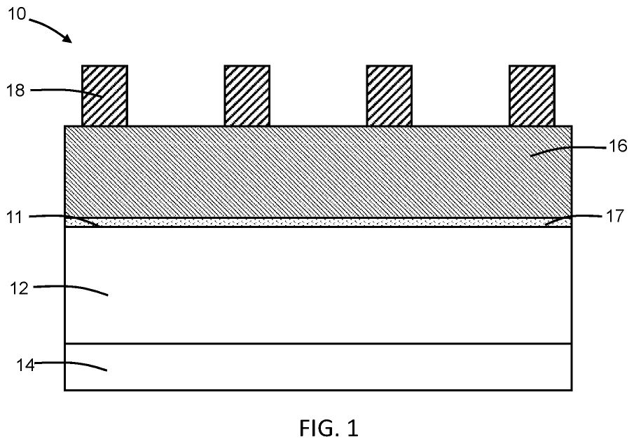

With reference to FIG. 1 and in accordance with embodiments of the invention, a structure 10 for a field-effect transistor includes a fin 12 that is arranged over, and projects upwardly away from, a substrate 14. The fin 12 and the substrate 14 may be composed of a single-crystal semiconductor material, such as single-crystal silicon. The fin 12 may be formed by patterning the substrate 14 with lithography and etching processes or by a self-aligned multi-patterning process. Shallow trench isolation (not shown) may surround a lower section of the fin 12.

A layer 16 of a material, such as polycrystalline silicon (i.e., polysilicon), and a layer 17 of a dielectric material, such as silicon dioxide, are successively formed over the fin 12 and shallow trench isolation. The layer 17 is arranged between the layer 16 and the fin 12. The layer 16 may be deposited by chemical vapor deposition, and the layer 17 may be formed by an oxidation process. Hardmask sections 18 are formed that are arranged over a top surface 11 of the fin 12 and that may extend across the shallow trench isolation. The hardmask sections 18 may be formed by patterning a layer of a dielectric material, such as silicon nitride, with lithography and etching processes. The hardmask sections 18 may be strips that have a parallel arrangement and a given uniform pitch.

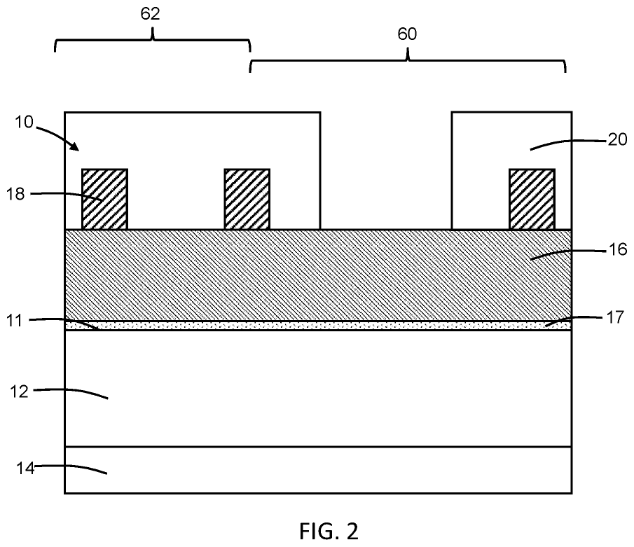

With reference to FIG. 2 in which like reference numerals refer to like features in FIG. 1 and at a subsequent fabrication stage, one or more of the hardmask sections 18 are removed by lithography and etching processes. In the representative embodiment, one of the hardmask sections 18 is removed from the top surface 11 of the fin 12. An etch mask 20, which may be formed by the lithography process, masks the hardmask sections 18 that are retained and that exposes the hardmask section 18 to be removed by etching. The etch mask 20 may include a layer of a light-sensitive material, such as a photoresist, applied by a spin-coating process, pre-baked, exposed to light projected through a photomask, baked after exposure, and developed with a chemical developer. The etching process may be a reactive ion etching process that removes the material of the hardmask section 18 selective to the material of the layer 16. As used herein, the terms “selective” and “selectivity” in reference to a material removal process (e.g., etching) denote that the material removal rate (i.e., etch rate) for the targeted material is higher than the material removal rate (i.e., etch rate) for at least another material exposed to the material removal. The etch mask 20 is stripped following patterning.

The removal of the hardmask section 18 locally increases the pitch of the hardmask sections 18 in a region 60. The original pitch is retained in the adjacent region 62. In particular, the pitch is locally doubled by the removal of the hardmask section 18. In an alternative embodiment, multiple adjacent hardmask sections 18 may be removed in region 60 to provide an additional increase in the local pitch. For example, a pair of adjacent hardmask section 18 may be removed to locally triple the pitch of the hardmask sections 18 in region 60.

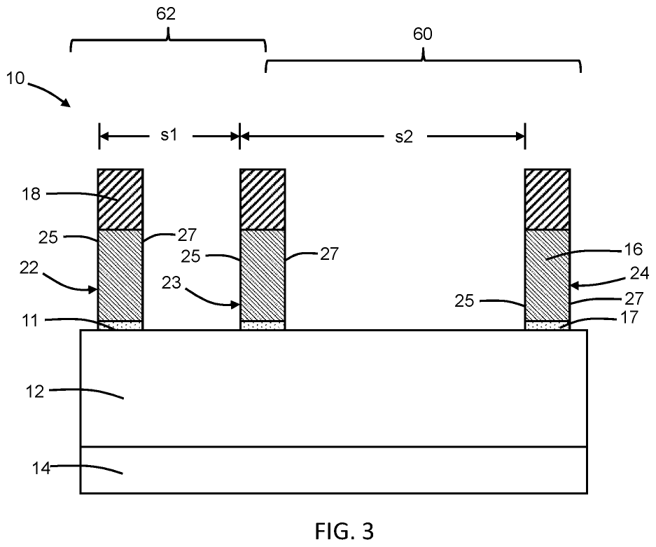

With reference to FIG. 3 in which like reference numerals refer to like features in FIG. 2 and at a subsequent fabrication stage, the layers 16, 17 are patterned to define gate structures 22, 23, 24 that extend laterally along respective longitudinal axes over and across the fin 12 and across the trench isolation. Each of the gate structures 22, 23, 24 is aligned transverse to the fin 12 and overlaps with, and wraps about, the fin 12. Each of the gate structures 22, 23, 24 has a sidewall 25 and a sidewall 27 that is opposite to the sidewall 25. The layer 16 may be patterned by an etching process, such as a reactive ion etching process, that is selective to the material of the fin 12 and that relies on the hardmask sections 18 as an etch mask. Each of the gate structures 22, 23, 24 may include, as a layer stack, a dummy gate composed of the material of layer 16 and a dielectric layer composed of the material of layer 17. The hardmask sections 18 are arranged as gate caps over the gate structures 22, 23, 24.

The gate structures 22, 23, 24, which are dummy elements, adopt the pattern, including the multiple pitches, of the hardmask sections 18. The result is that the sidewall 25 of the gate structure 22 and the sidewall 25 of the gate structure 23 are separated by a spacing, s1, and the sidewall 25 of the gate structure 23 and the sidewall 25 of the gate structure 24 are separated by a spacing, s2, that is greater than the spacing, s1. In an embodiment, the spacing, s2, may be equal or approximately equal to twice the spacing, s1. In such an embodiment, the gate structures 22, 23 may have a 1CPP (contacted (poly) pitch) gate pitch and the gate structures 23, 24 may have a 2CPP gate pitch. In other embodiments, the spacing, s2, may be equal or approximately equal to an integer multiple of the spacing, s1, contingent upon the number of hardmask sections 18 removed from region 60. In an embodiment in which the integer is three (3) and the gate structure 24 is removed, the gate structure 23 and the gate structure (not shown) adjacent to the removed gate structure 24 may have a 3CPP gate pitch.

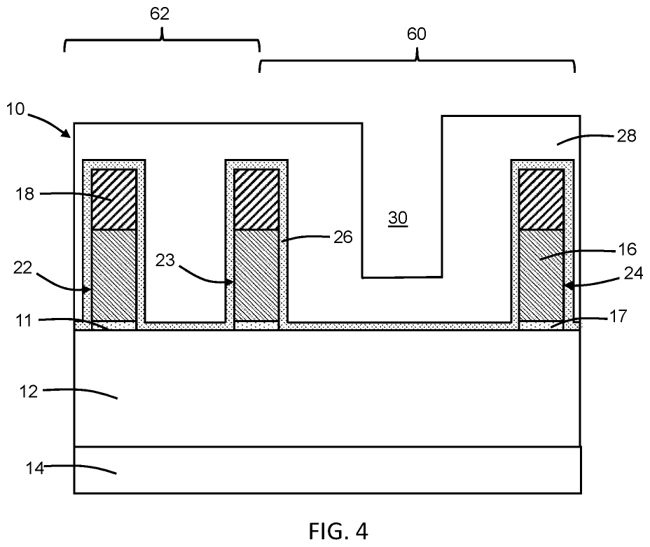

With reference to FIG. 4 in which like reference numerals refer to like features in FIG. 3 and at a subsequent fabrication stage, a conformal layer 26 composed of, for example, a low-k dielectric material is deposited as a liner over the gate structures 22, 23, 24 and fin 12 by, for example, atomic layer deposition. The conformal layer 26 may have a uniform thickness that is independent or substantially independent of position.

A layer 28 composed of, for example, silicon dioxide is deposited over the conformal layer 26 on the gate structures 22, 23, 24 and fin 12. The layer 28 may pinch off in the space between the gate structure 22 and the gate structure 23 such that this space is fully filled. The layer 28 does not pinch off in the space between the gate structure 23 and the gate structure 24 such that this space is only partially filled. In particular, the layer 28 narrows the width of the space between the gate structures 23, 24 and effectively defines a trench 30. The opposite sidewalls of the trench 30 may be located equidistant or substantially equidistant from the gate structure 23 and the gate structure 24.

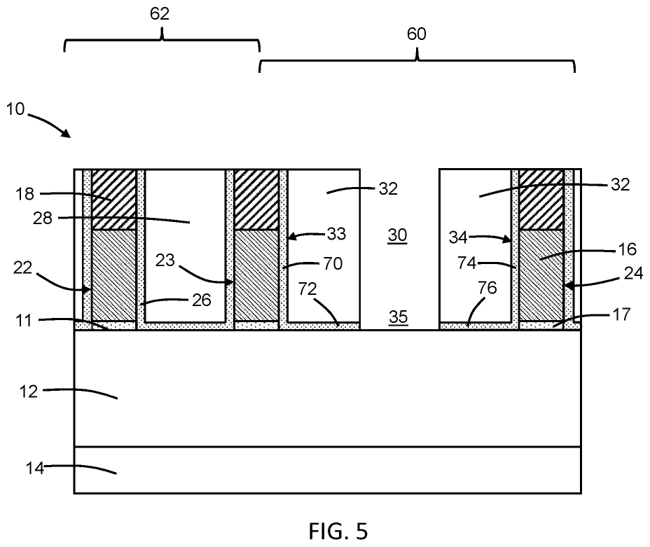

With reference to FIG. 5 in which like reference numerals refer to like features in FIG. 4 and at a subsequent fabrication stage, the trench 30 is extended by an anisotropic etching process, such as reactive ion etching, to penetrate through the layer 28 to the conformal layer 26. Spacers 32 are effective formed from the layer 28 in the space between trench 30 and the gate structure 23 and in the space between the trench 30 and the gate structure 24. Both of the spacers 32 are arranged in a lateral direction between the gate structure 23 and the gate structure 24. The trench 30 is extended by the etching process in a vertical direction to the conformal layer 26 on the top surface 11 of the fin 12.

The conformal layer 26 is then etched with an anisotropic etching process, such as reactive ion etching, using the spacers 32 as an etch mask, to define an opening 35 in the conformal layer 26 that exposes an area on the top surface 11 of the fin 12. The etched conformal layer 26 defines spacers 33, 34 that are L-shaped. The spacer 33 includes a section 70 on the gate structure 23 and a section 72 extending in a lateral direction from the section 70 on the gate structure 23 to the opening 35. The spacer 34 includes a section 74 on the gate structure 24 and a section 76 extending in a lateral direction from the section 74 on the gate structure 24 to the opening 35. The sections 72, 76 are located on the top surface 11 of the fin 12, and the opening 35 is positioned laterally between the section 72 of the spacer 33 and the section 76 of the spacer 34. The section 72 of the spacer 33 adjoins and is continuous with the section 70 of the spacer 33, and the section 76 of the spacer 34 adjoins and is continuous with the section 74 of the spacer 34.

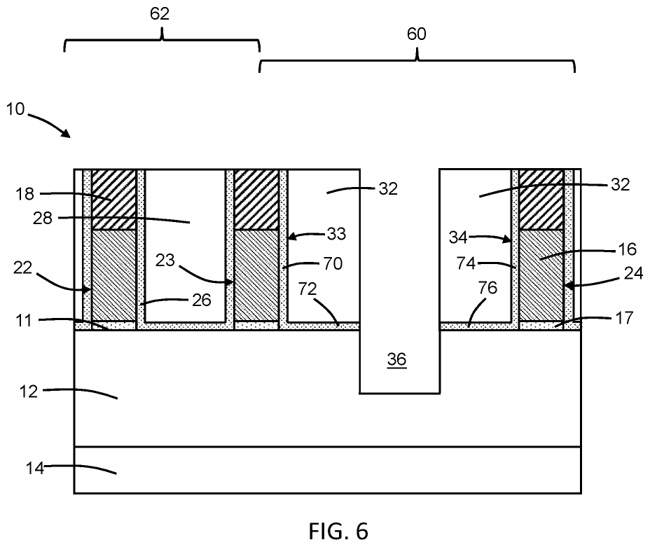

With reference to FIG. 6 in which like reference numerals refer to like features in FIG. 5 and at a subsequent fabrication stage, a cavity 36 is formed by an etching process, such as an anisotropic etching process (e.g., reactive ion etching), in a portion of the fin 12 that is laterally between the gate structure 23 and the gate structure 24. The cavity 36 is formed at the location of the trench 30 and the opening 35 (FIG. 5) between the section 72 of the spacer 33 and the section 76 of the spacer 34, and the spacers 32 again function as an etch mask. The opposite sidewalls of the cavity 36 may be located equidistant from the gate structure 23 and the gate structure 24 (i.e., symmetrical positioning between the gate structure 23 and the gate structure 24).

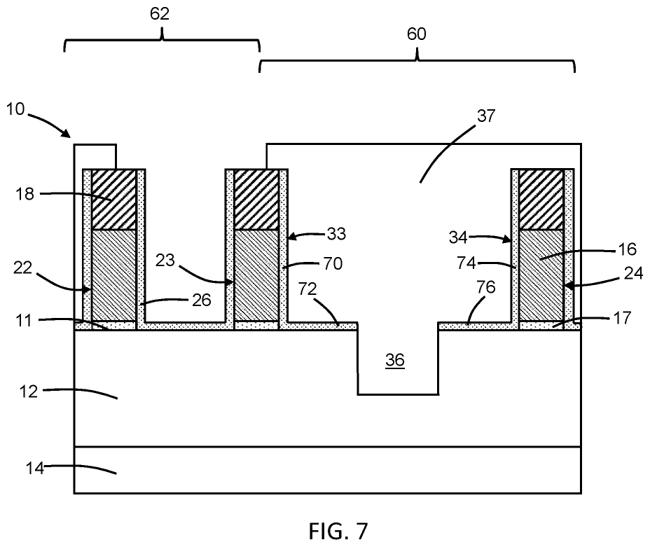

With reference to FIG. 7 in which like reference numerals refer to like features in FIG. 6 and at a subsequent fabrication stage, the layer 28 and spacers 32 are removed with an etching process, which may be a wet chemical etching process that removes silicon dioxide selective to the materials of the conformal layer 26 and hardmask sections 18. A block mask 37 is formed that covers the portion of the fin 12 between the gate structure 23 and the gate structure 24. The block mask 37 may be a spin-on hardmask composed of an organic material that is patterned with lithography and etching processes. The portion of the conformal layer 26 between the gate structure 22 and the gate structure 23 is exposed by the patterned block mask 37.

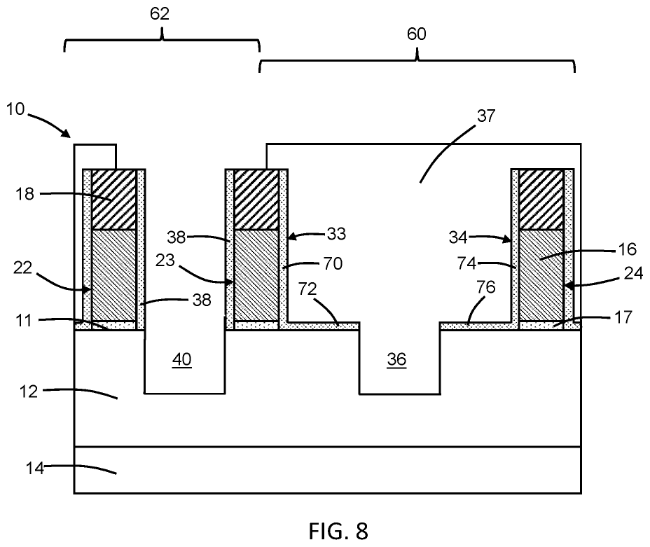

With reference to FIG. 8 in which like reference numerals refer to like features in FIG. 7 and at a subsequent fabrication stage, spacers 38 are formed in the space between the gate structure 22 and the gate structure 23 by etching the conformal layer 26 with an anisotropic etching process, such as reactive ion etching. A portion of the fin 12 is exposed laterally between the spacers 38. A cavity 40 is formed by an etching process, such as an anisotropic etching process (e.g., reactive ion etching), in the exposed portion of the fin 12 laterally between the gate structure 22 and the gate structure 23. The block mask 37 operates as an etch mask to protect the spacers 33, 34 and the fin 12 between the gate structures 23, 24 during the etching process forming the cavity 40. The block mask 37 may be stripped by, for example, an ashing process after the cavity 40 is formed. In an embodiment, the cavity 40 may have the same size (i.e., dimensions) as the cavity 36.

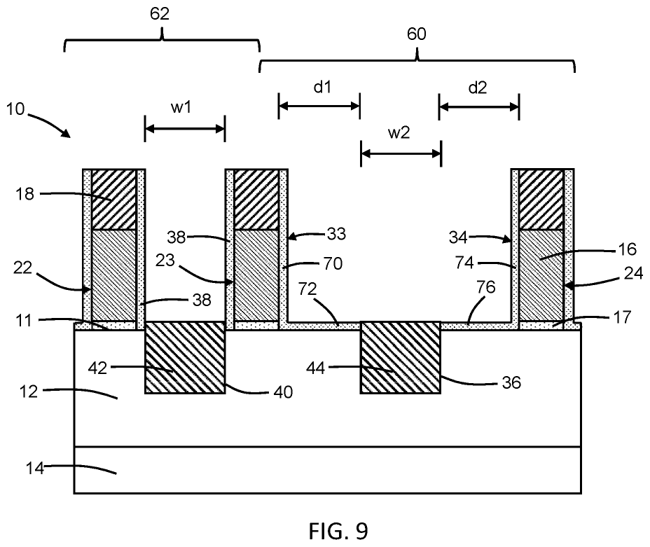

With reference to FIG. 9 in which like reference numerals refer to like features in FIG. 8 and at a subsequent fabrication stage, a layer 42 of a semiconductor material is grown by an epitaxial growth process from the surfaces of the fin 12 bordering the cavity 36, and a layer 44 of a semiconductor material is grown by an epitaxial growth process from the surfaces of the fin 12 bordering the cavity 40. The layers 42, 44 may be concurrently formed by the same epitaxial growth process. The layer 42 may extend laterally outward from the space between the gate structures 22, 23 with a faceted shape, and the layer 44 may extend also laterally outward from the space between the gate structures 23, 24 with a faceted shape.

The epitaxial growth process forming the layers 42, 44 may be selective in that the semiconductor material does not grow from dielectric surfaces, such as the hardmask sections 18, the spacers 33, 34, and the spacers 38. The layers 42, 44 may be in situ doped during epitaxial growth with a concentration of a dopant. In an embodiment, the layers 42, 44 may be in situ doped during epitaxial growth with a p-type dopant (e.g., boron) that provides p-type conductivity. In an alternative embodiment, the layers 42, 44 may be in situ doped during epitaxial growth with an n-type dopant (e.g., phosphorus and/or arsenic) that provides n-type conductivity. The layers 42, 44 may have a composition that contains germanium and silicon and, in an embodiment, the layers 42, 44 may be composed of silicon-germanium. In an embodiment, the layers 42, 44 may be composed of silicon-germanium and may contain a p-type dopant. In an embodiment, the layers 42, 44 may be composed of silicon. In an embodiment, the layers 42, 44 may be composed of silicon and may contain an n-type dopant.

The layer 44 is constrained during epitaxial growth by the spacers 33, 34 located at the entrance to the cavity 36. The layer 44 only grows from the portion of the fin 12 that is exposed by the opening 35 between the section 72 of the spacer 33 and the section 76 of the spacer 34 because of the constraint provided by the spacers 33, 34. The section 72 of the spacer 33 and the section 76 of the spacer 34 effectively narrow the portion of the fin 12 from which the layer 44 is permitted to epitaxially grow. The layer 42 has a width, w1, and the layer 44 has a width, w2. In an embodiment, the width, w2, of the layer 42 may be equal to the width, w1, of the layer 44. The width of the layer 44 is decreased by the presence of the section 72 of the spacer 33 and the section 76 of the spacer 34 in the region 60 having a larger gate pitch than region 62. The cavity 36 and layer 44 are spaced laterally by a distance, d1, from the gate structure 23 and the cavity 36 and layer 44 is spaced laterally by a distance, d2, from the gate structure 24. The distances d1 and d2 may be equal.

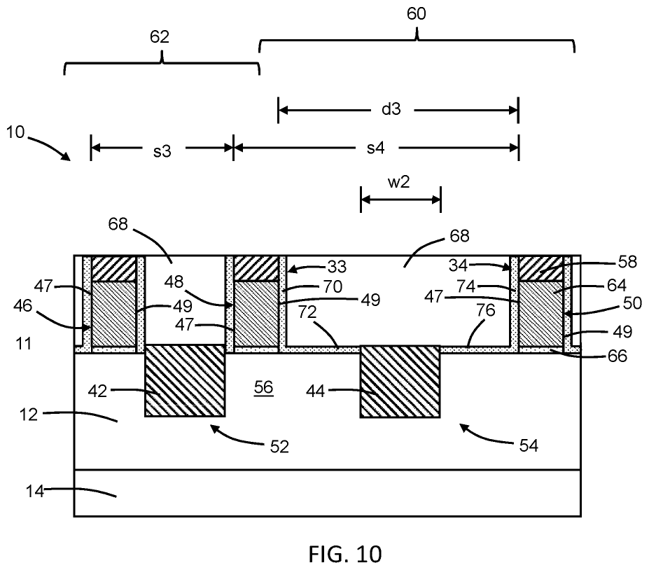

With reference to FIG. 10 in which like reference numerals refer to like features in FIG. 9 and at a subsequent fabrication stage, a replacement gate process is performed to replace the gate structures 22, 23, 24 with gate structures 46, 48, 50 and to complete the structure 10 for the field-effect transistor. The gate structures 46, 48, 50 may include a layer 64 composed of one or more metal gate materials, such as work function metals, and a layer 66 composed of a dielectric material, such as a high-k dielectric material like hafnium oxide. Each of the gate structures 46, 48, 50 has opposite side surfaces or sidewalls 47, 49. A gate cap 58 composed of, for example, silicon nitride may be positioned over each of the gate structures 46, 48, 50.

The gate structures 46, 48, 50 adopt the pattern, including the multiple pitches, of the gate structures 22, 23, 24 as a result of the replacement gate process. The result is that the sidewall 47 of the gate structure 46 and the sidewall 47 of the gate structure 48 are separated by a spacing, s3, and the sidewall 47 of the gate structure 48 and the sidewall 47 of the gate structure 50 are separated by a spacing, s4, that is greater than the spacing, s3. In an embodiment, the spacing, s4, may be equal or approximately equal to twice the spacing, s3. In this embodiment, the gate structures 46, 48 may have a 1CPP (contacted (poly) pitch) gate pitch and the gate structures 48, 50 may have a 2CPP gate pitch. In other embodiments, the spacing, s4, may be equal or approximately equal to an integer multiple of the spacing, s3, contingent upon the number of adjacent hardmask sections 18 that were previously removed. In an embodiment in which the integer is three (3), the gate structure 50 is absent, and the gate structure 48 and a gate structure (not shown) adjacent to the gate structure 48 may have a 3CPP gate pitch.

The sidewall 49 of the gate structure 48 and the sidewall 47 of the gate structure 50 are separated by a distance, d3. The distance, d3, is greater than the width, w2, of the layer 44. The section 72 of the spacer 33 and the section 76 of the spacer 34 promote the width difference by constraining the epitaxial growth of the layer 44. The section 70 of the spacer 33 is arranged on the sidewall 49 of the gate structure 48, and the section 74 of the spacer 34 is arranged on the sidewall 47 of the gate structure 50. The section 72 of the spacer 33 is arranged between the layer 44 and the sidewall 49 of the gate structure 48. The section 76 of the spacer 34 is arranged between the layer 44 and the sidewall 47 of the gate structure 50.

The structure 10 includes an embedded source/drain region 52 provided by the layer 42 and an embedded source/drain region 54 provided by the layer 44. As used herein, the term “source/drain region” means a doped region of semiconductor material that can function as either a source or a drain of a field-effect transistor. The source/drain region 52 is positioned laterally between the gate structure 46 and the gate structure 48, and the source/drain region 54 is positioned laterally between the gate structure 48 and the gate structure 50. The fin 12 provides a semiconductor body used to form the source/drain regions 52, 54, which have an asymmetrical arrangement relative to the gate structure 48. A channel region 56 is disposed in the fin 12 laterally between the source/drain region 52 and the source/drain region 54 and vertically beneath the overlying gate structure 48. Sections of an interlayer dielectric layer 68 may be located in the spaces between the gate structures 46, 48, 50 that are over the source/drain regions 52, 54.

In an embodiment, the source/drain region 52 may provide a source in the structure 10 for the field-effect transistor, and the source/drain region 54 may provide a drain in the structure 10 for the field-effect transistor. In an alternative embodiment, the source/drain region 52 may provide a drain in the structure 10 for the field-effect transistor, and the source/drain region 54 may provide a source in the structure 10 for the field-effect transistor. The source/drain regions 52, 54 are doped to have a conductivity type of the same polarity (i.e., the same conductivity type). The same epitaxial semiconductor geometry is provided by the layer 44 located on the drain side of the field-effect transistor and the layer 42 located on the source side of the field-effect transistor.

Middle-of-line processing and back-end-of-line processing follow, which includes formation of contacts, vias, and wiring for an interconnect structure that is coupled with the field-effect transistor.

A field-effect transistor with the source/drain region 52 providing the source and the source/drain region 54 providing the drain may exhibit improvements in filling by the epitaxial semiconductor material because of the spacers 33, 34 that compensates for the larger gate pitch on the drain side than on the source side. The larger gate pitch on the drain side may improve radiofrequency performance (e.g., improvements in power gain, cut-off frequency (f_{T}), and maximum oscillation frequency (f_{Max})) in comparison with a conventional field-effect transistor having a 1CPP gate pitch for gate structures on the source side and on the drain side. The structure 10 may include additional gate structures with the varied gate pitches, and the embedded source/drain regions 52, 54 may be repeated for the pairs of the gate structures to form a multi-gate field-effect transistor for use in a radiofrequency integrated circuit.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact ” with another feature if intervening features are absent. A feature may be “indirectly on” or in “indirect contact” with another feature if at least one intervening feature is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure for a field-effect transistor, the structure comprising:
a semiconductor fin;
a first gate structure that extends over the semiconductor fin, the first gate structure including a first sidewall and a second sidewall opposite the first sidewall;
a second gate structure that extends over the semiconductor fin, the second gate structure including a sidewall adjacent to the first sidewall of the first gate structure;
a first L-shaped spacer including a first section on the first sidewall of the first gate structure and a second section extending laterally from the first section, the first section and the second section of the first L-shaped spacer having a uniform thickness;
a second L-shaped spacer including a first section on the sidewall of the second gate structure and a second section extending laterally over the first section, the first section and the second section of the second L-shaped spacer having a uniform thickness;
a first source/drain region including a first epitaxial semiconductor layer positioned between the second section of the first L-shaped spacer and the second section of the second L-shaped spacer; and
a second source/drain region including a second epitaxial semiconductor layer positioned adjacent to the second sidewall of the first gate structure,
wherein the first epitaxial semiconductor layer has a first width, and the first sidewall of the first gate structure and the sidewall of the second gate structure are separated by a distance that is greater than the first width of the first epitaxial semiconductor layer.

2-4. (canceled)

5. The structure of claim 1 wherein the first epitaxial semiconductor layer is positioned in a first cavity in the semiconductor fin.

6. The structure of claim 5 wherein the second epitaxial semiconductor layer is positioned in a second cavity in the fin, the second epitaxial semiconductor layer has a second width, and the first width of the first epitaxial semiconductor layer is substantially equal to the second width of the second epitaxial semiconductor layer.

7. The structure of claim 1 further comprising:
a third gate structure that extends over the semiconductor fin, the third gate structure positioned adjacent to the second sidewall of the first gate structure,
wherein the second source/drain region is laterally positioned between the second sidewall of the first gate structure and the third gate structure.

8. The structure of claim 7 wherein the third gate structure has a sidewall, the second sidewall of the first gate structure and the sidewall of the second gate structure are separated by a first spacing, the second sidewall of the first gate structure and the sidewall of the third gate structure are separated by a second spacing, and the first spacing is greater than the second spacing.

9. The structure of claim 8 wherein the first spacing is equal to an integer multiple of the second spacing.

10. The structure of claim 8 wherein the first spacing is equal to two times the second spacing.

11. A structure structure for a field-effect transistor, the structure comprising:
a semiconductor body;
a first gate structure that extends over the semiconductor body, the first gate structure including a first sidewall and a second sidewall opposite the first sidewall;
a second gate structure that extends over the semiconductor body, the second gate structure including a sidewall adjacent to the first sidewall of the first gate structure;
a first source/drain region including a first epitaxial semiconductor layer positioned between the first sidewall of the first gate structure and the sidewall of the second gate structure; and
a second source/drain region including a second epitaxial semiconductor layer positioned adjacent to the second sidewall of the first gate structure,
wherein the first epitaxial semiconductor layer has a first width, the first sidewall of the first gate structure and the sidewall of the second gate structure are separated by a distance that is greater than the first width of the first epitaxial semiconductor layer, the second epitaxial semiconductor layer has a second width, and the first width of the first epitaxial semiconductor layer is equal to the second width of the second epitaxial semiconductor layer.

12. The structure of claim 1 wherein the first source/drain region is a drain of the field-effect transistor, and the second source/drain region is a source of the field-effect transistor.

13. A method of forming a structure for a field-effect transistor, the method comprising:
forming a first gate structure that extends over a semiconductor fin, wherein the first gate structure includes a first sidewall and a second sidewall opposite the first sidewall;
forming a second gate structure that extends over the semiconductor fin, wherein the second gate structure includes a sidewall adjacent to the first sidewall of the first gate structure;
forming a first L-shaped spacer including a first section on the first sidewall of the first gate structure and a second section extending laterally from the first section, wherein the first section and the second section of the first L-shaped spacer have a uniform thickness;
forming a second L-shaped spacer including a first section on the sidewall of the second gate structure and a second section extending laterally over the first section, wherein the first section and the second section of the second L-shaped spacer have a uniform thickness;
forming a first epitaxial semiconductor layer of a first source/drain region on the semiconductor body; and
forming a second epitaxial semiconductor layer of a second source/drain region on the semiconductor body,
wherein the first epitaxial semiconductor layer is positioned between the second section of the first L shaped spacer and the second section of the second L-shaped spacer, the second source/drain region is positioned adjacent to the second sidewall of the first gate structure, the first epitaxial semiconductor layer has a first width, and the first sidewall of the first gate structure and the sidewall of the second gate structure are separated by a distance that is greater than the first width of the first epitaxial semiconductor layer.

14-15. (canceled)

16. The method of claim 13 wherein the first epitaxial semiconductor layer is formed in a cavity in the semiconductor fin.

17. The method of claim 13 further comprising:
forming a third gate structure that extends over the semiconductor fin,
wherein the third gate structure is positioned adjacent to the second sidewall of the first gate structure, and the second source/drain region is laterally positioned between the second sidewall of the first gate structure and the third gate structure.

18. The method of claim 17 wherein the third gate structure has a sidewall, the second sidewall of the first gate structure and the sidewall of the second gate structure are separated by a first spacing, the second sidewall of the first gate structure and the sidewall of the third gate structure are separated by a second spacing, and the first spacing is greater than the second spacing.

19. The method of claim 18 wherein the first spacing is equal to an integer multiple of the second spacing.

20. The method of claim 13 wherein the second epitaxial semiconductor layer has a second width, and the first width of the first epitaxial semiconductor layer is substantially equal to the second width of the second epitaxial semiconductor layer.

21. The structure of claim 11 wherein the semiconductor body is a semiconductor fin, and further comprising:
a first L-shaped spacer including a first section on the semiconductor fin; and
a second L-shaped spacer including a first section on the semiconductor fin,
wherein the first epitaxial semiconductor layer is positioned between the first section of the first L-shaped spacer and the first section of the second L-shaped spacer.

22. The structure of claim 21 wherein the first L-shaped spacer includes a second section on the first sidewall of the first gate structure, the first section of the first L-shaped spacer extends laterally from the second section of the first L-shaped spacer, the second L-shaped spacer includes a second section on the sidewall of the second gate structure, and the first section of the second L-shaped spacer extends laterally from the second section of the first L-shaped spacer.

23. The structure of claim 22 wherein the first epitaxial semiconductor layer is positioned in a first cavity in the semiconductor fin.

24. The structure of claim 23 wherein the second epitaxial semiconductor layer is positioned in a second cavity in the fin.

25. The structure of claim 11 wherein the first source/drain region is a drain of the field-effect transistor, and the second source/drain region is a source of the field-effect transistor.
